(19) United States
(12) Patent Application Publication
(10) Pub. No.: US 2025/0299990 A1
(43) Pub. Date: Sep. 25, 2025

(54) SUBSTRATE PROCESSING APPARATUS, SUBSTRATE FALL PREVENTER, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Shigenori TEZUKA, Toyama-shi (JP); Akinari HAYASHI, Toyama-shi (JP); Toshiharu KUROSAWA, Toyama-shi (JP)

(73) Assignee: Kokusai Electric Corporation, Tokyo (JP)

(21) Appl. No.: 19/057,708

(22) Filed: Feb. 19, 2025

(30) Foreign Application Priority Data
Mar. 19, 2024 (JP) 2024-043362

(51) Int. Cl. H01L 21/673; H01L 21/677

(52) U.S. Cl. CPC H01L 21/67373; H01L 21/67769

(57) ABSTRACT

There is provided a technique that includes: a container storage configured to store at least one container configured to accommodate substrates; and (b) at least one fall preventer a part of which is installed to be movable between a first position that does not hinder transfer of the at least one container and a second position that prevents the at least one container stored in the container storage or the substrates in the at least one container from falling.

### CROSS-REFERENCE TO RELATED APPLICATION

This application is based upon and claims the benefit of priority from Japanese Patent Application No. 2024-043362, filed on Mar. 19, 2024, the entire contents of which are incorporated herein by reference.

### TECHNICAL FIELD

The present disclosure relates to a substrate processing apparatus, a substrate fall preventer, a method of processing a substrate, a method of manufacturing a semiconductor device, and a recording medium.

### BACKGROUND

When an earthquake occurs, vibrations of an initial tremor (P) wave and a main shaking (S) wave may be detected to perform a stop operation of a transporter of a processing apparatus.

In a case where the transporter stops working when an earthquake occurs, a substrate cassette may fall from a spare cassette shelf.

### SUMMARY

Some embodiments of the present disclosure provide a technique capable of preventing a substrate cassette stored on a spare cassette shelf in an apparatus from falling due to shaking such as an earthquake or the like.

According to some embodiments of the present disclosure, there is provided a technique that includes: a container storage configured to store at least one container configured to accommodate substrates; and (b) at least one fall preventer a part of which is installed to be movable between a first position that does not hinder transfer of the at least one container and a second position that prevents the at least one container stored in the container storage or the substrates in the at least one container from falling.

### BRIEF DESCRIPTION OF DRAWINGS

The accompanying drawings, which are incorporated in and constitute a part of the specification, illustrate embodiments of the present disclosure.

FIG. 1 is a diagram for explaining a substrate processing apparatus according to some embodiments of the present disclosure.

FIG. 2 is a schematic rear view of a spare cassette shelf according to some embodiments of the present disclosure.

FIG. 3 is a schematic left-side view of a spare cassette shelf according to some embodiments of the present disclosure.

FIG. 4 is a schematic top view of a spare cassette shelf according to some embodiments of the present disclosure and a diagram showing a position of a stopper.

FIG. 5 is a perspective view of a fixed stopper installed on a cassette shelf.

FIG. 6 is a block diagram of a controller and its periphery.

FIG. 7 is a diagram showing an overall processing flow including an operation of a stopper of the spare cassette shelf according to some embodiments of the present disclosure.

FIG. 8A is a diagram explaining an operation of a stopper before a cassette is loaded on a spare cassette shelf according to some embodiments.

FIG. 8B is a diagram explaining an operation of a stopper after a cassette is loaded on a spare cassette shelf according to some embodiments of the present disclosure.

FIG. 9 is a block diagram of a controller and its periphery according to other embodiments of the present disclosure.

FIG. 10 is a diagram explaining an operation flow of a stopper of a spare cassette shelf according to other embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, some embodiments of the present disclosure will be described with reference to the drawings. Drawings used in the following description are schematic, and dimensional relationships, ratios, and the like among the respective components shown in the drawings may not match actual ones. In addition, dimensional relationships, ratios, and the like of the respective components may not match one another among multiple drawings. In addition, substantially the same components are designated by the same reference numerals among multiple drawings. Each component is explained in the drawing in which the component first appears, and the explanation is omitted in the subsequent drawings unless particularly desired. Unless otherwise specified in the present disclosure, each component is not limited to one, and may be present in multiple numbers.

### Embodiment

### (1) Substrate Processing Apparatus

In the embodiments of the present disclosure, a substrate processing apparatus (hereinafter also simply referred to as a processing apparatus) is constituted as, as an example, a semiconductor manufacturing apparatus configured to perform a processing step in a method of manufacturing a semiconductor device.

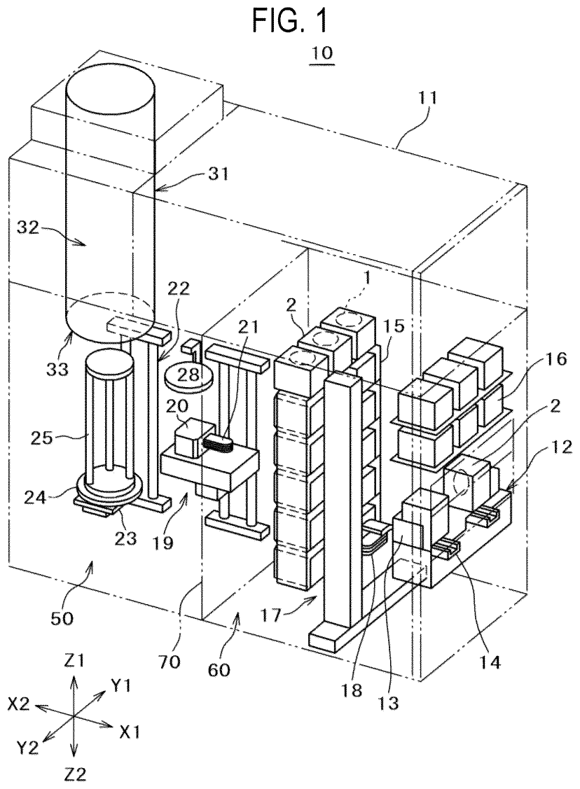

As shown in FIG. 1, the processing apparatus 10 according to some embodiments of the present disclosure includes a housing 11, and a cassette delivery unit 12 is installed on a front side (X1 side) of the housing 11. An X1-X2 direction is a front-rear direction, a Y2-Y1 direction is a left-right direction, and a Z1-Z2 direction is an up-down direction of the processing apparatus 10. The cassette delivery unit 12 includes a cassette stage 13 capable of mounting two open cassettes (hereinafter, simply referred to as cassettes) 2 as containers configured to accommodate substrates that are carriers for wafers 1 as the substrates. Further, two sets of wafer posture aligners 14 are installed below the cassette stage 13. In other words, the cassette stage 13 includes a plurality of stages, and each stage is configured to be capable of delivering the cassette 2 to or from an outside of the apparatus.

The cassette 2 transferred by an external transfer apparatus (not shown) is mounted on the cassette stage 13. The wafer posture aligner 14 includes an orientation aligner configured to align postures of the wafers 1 such that notches or orientation flats as orientation specifiers of the wafers 1 stored in the cassette 2 are aligned when the cassette 2 is in a vertical posture. The cassette stage 13 includes a cassette inverter configured to rotate a mounting stand (not shown) by 90 degrees to put the cassette 2 in a horizontal posture (a state in which the wafers 1 are vertically arranged and stored) as a second posture. Inside the housing 11, a cassette shelf 15 as a main storage is installed to face the cassette delivery unit 12. In addition, a spare cassette shelf 16 as a container storage configured to store containers configured to accommodate the wafers 1 is installed over the cassette delivery unit 12.

Between the cassette delivery unit 12 and the cassette shelf 15, a cassette transfer robot 17 is installed as a cassette transfer apparatus configured to move the cassette 2 to or from the spare cassette shelf 16. The cassette transfer robot 17 includes a robot arm 18 including a hand (not shown) configured to be capable of advancing or retreating in the front-rear direction (X1-X2 direction), and the robot arm 18 itself is configured to be capable of performing a lateral movement and an elevating movement. By the elevating movement and the lateral movement of the robot arm 18 and the advancing-retreating (front-rear) movement of the hand, the cassette 2 on the cassette stage 13 is lifted from below and is transferred and delivered to the cassette shelf 15 or the spare cassette shelf 16. The cassette shelf 15 and the spare cassette shelf 16 may be also regarded as buffer shelves for a plurality of cassettes 2. Since the cassette stage 13 includes the cassette inverter, both the orientation alignment by the wafer posture aligner 14 and the cassette transfer by the cassette transfer robot 17 may be performed.

A wafer transfer apparatus (transfer machine) 19 configured to be capable of transferring the wafers 1 in the cassette 2 to a substrate support (hereinafter, referred to as a boat) 25 either collectively or one by one is installed on a rear side of the cassette shelf 15 (X2 side) in such a manner that the wafer transfer apparatus 19 is capable of rotating and elevating. The wafer transfer apparatus 19 includes a wafer holder 20 which may advance or retreat. A plurality of wafer holding plates 21 are attached horizontally to the wafer holder 20. A boat elevator 22 is installed on a rear side of the wafer transfer apparatus 19 (X2 side). A seal cap 24 configured to rotatably hold the boat 25 is horizontally installed at an arm 23 of the boat elevator 22.

The processing apparatus 10 includes a transfer chamber 50 and a cassette holding chamber 60. The transfer chamber 50 is equipped with the wafer transfer apparatus 19, the wafer holder 20, the wafer holding plate 21, the boat elevator 22, and the like. The cassette holding chamber 60 is equipped with the cassette shelf 15, the spare cassette shelf 16, the cassette transfer robot 17, and the like. A wall 70 is installed between the transfer chamber 50 and the cassette holding chamber 60. The wafer transfer apparatus 19 transfers the wafer 1 from the cassette 2 in the cassette holding chamber 60 to the boat 25.

The processing apparatus 10 includes a reaction tube (process tube, or process furnace) 31 made of a highly heat-resistant material such as quartz glass or the like and formed into a cylindrical shape with one end open and the other end closed. The reaction tube 31 is vertically arranged with its center line extending in the vertical direction and is fixedly supported. A cylindrical hollow area of the reaction tube 31 forms a process chamber 32 in which a plurality of wafers 1 are accommodated. A lower end opening of the reaction tube 31 forms a furnace port 33 configured to load or unload the wafers 1. The furnace port 33 is opened into the transfer chamber 50. The process chamber 32 and the transfer chamber 50 are connected to each other.

A seal cap 24 configured to close the furnace port 33 is adapted to be in contact with a lower end surface of the reaction tube 31 from below in the vertical direction. The seal cap 24 is formed in a disc shape and is configured to be raised or lowered in the vertical direction by the boat elevator 22 installed outside the reaction tube 31. In addition, a furnace port shutter 28 configured to seal the furnace port 33 when the seal cap 24 is moved to a lower end position may be installed.

A boat 25 configured to hold the wafers 1 is supported vertically on the seal cap 24. The boat 25 includes a pair of upper and lower end plates 26 and 27 and a plurality of (three, in the embodiments) holders (pillars) vertically arranged between the end plates 26 and 27. Each holder includes a number of holding grooves that are equally spaced in a longitudinal direction and opened to face each other. Outer peripheral edges of the wafers 1 are respectively inserted into the holding grooves of each holder, such that the wafers 1 are held in the boat 25 horizontally with centers of the wafers 1 aligned with one another.

### (Spare Cassette Shelf)

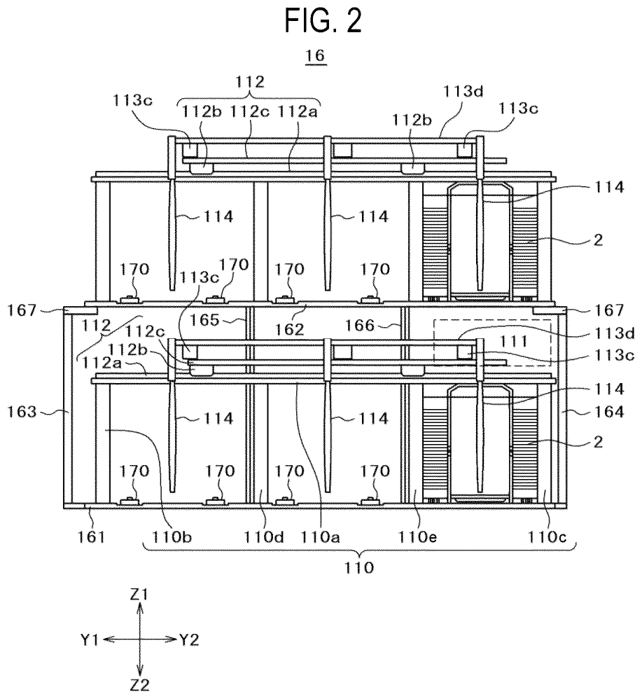

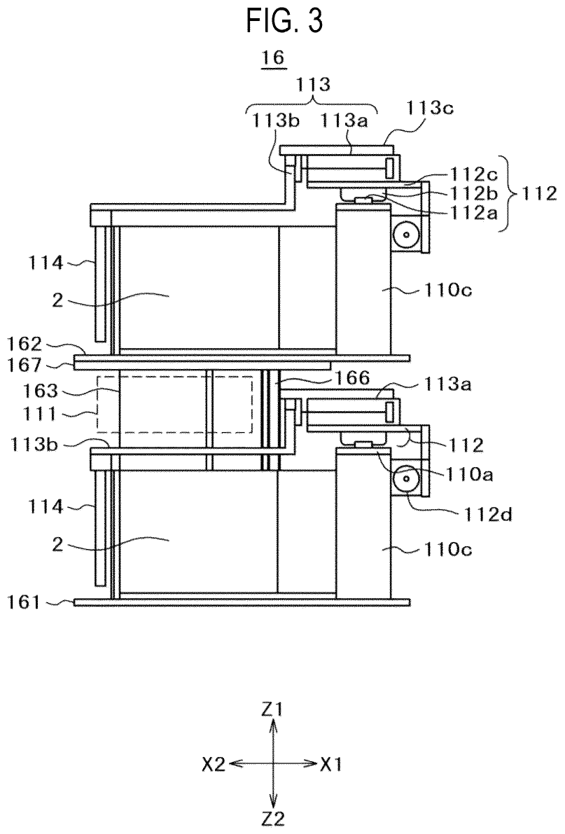

Next, the spare cassette shelf 16 into which the cassette 2 is loaded from the cassette stage 13 installed in the processing apparatus 10 will be described with reference to FIGS. 2 to 4.

The spare cassette shelf 16 is configured to hold the cassette 2 with the opening of the cassette 2 facing the same direction (X2 direction) as a direction in which the cassette transfer robot 17 takes out the cassette 2 from the spare cassette shelf 16. The spare cassette shelf 16 is configured to be capable of mounting a plurality of cassettes 2 along a surface parallel to the opening through which the wafers 1 are inserted or removed. In the spare cassette shelf 16, three cassettes 2 may be mounted in the Y direction on each of a lower plate 161 and an upper plate 162, each of which is provided with a cassette stopper 170. Between the lower plate 161 and the upper plate 162, a substantially rectangular Y1-side lateral support 163, a substantially rectangular Y2-side lateral support 164, a Y1-side central support 165, and a Y2-side central support 166, which extend in the Z direction, are installed. Further, shelf plates 167 are also installed to support the upper plate 162 and the supports 163 and 164 respectively. Further, a frame 110 at least partially arranged over the cassette 2 and fixed to the spare cassette shelf 16 is installed. The frame 110 is installed on the X1 side of the lower plate 161 and the upper plate 162. The frame 110 includes an upper frame 110a extending in the Y direction, a frame 110b erected from a Y1-side upper surface of the lower plate 161 to support the upper frame, a frame 110c erected from a Y2-side upper surface to support the upper frame, a frame 110d erected from a Y1-side central upper surface to support the upper frame, and a frame 110e erected from a Y2-side central upper surface to support the upper frame. The frame 110 is configured such that a plurality of cassettes 2 may be stored in the frame 110 in the Y direction. In addition, an area 111 into which the robot arm 18 of the cassette transfer robot 17 configured to transport the cassette 2 to the cassette shelf 15 enters is provided over the upper frame 110a. This frame structure is installed inside the spare cassette shelf 16.

At the frame 110, a first driver 112 configured to move linearly in a direction (Y direction) approximately parallel to the opening through which the wafer 1 is inserted or removed, a second driver 113 configured to move linearly in a direction (X direction) approximately perpendicular to the opening, and a stopper 114 configured to prevent the fall of the wafer moved by the first driver 112 and the second driver 113 are installed. A fall preventer is constituted by the first driver 112, the second driver 113, and the stopper 114. The first driver 112 includes a linear guide (rail) 112a installed on the upper frame 110a to extend in the Y direction, two movable parts (carriages) 112b configured to move along the linear guide 112a, a mounting plate 112c supported by the movable parts, and a first cylinder 112d as a first actuator configured to push or pull the mounting plate 112c in the Y direction. The second driver 113 is installed on the mounting plate 112c. The second driver 113 includes a second cylinder 113a as a second actuator, a plurality of arms 113b, a mounting plate 113c to which the plurality of arms 113b are fixed, and a linear guide 113d configured to support the mounting plate 113c such that the mounting plate 113c may move in two X directions. Since the stopper 114 is installed for each of the plurality of cassettes 2, it is possible to prevent many cassettes from falling with a small number of drivers.

As described above, an area 111 is provided over the frame 110. Since the robot arm 18 enters the area 111 when loading or unloading the cassette 2 into or from the spare cassette shelf 16, space saving is desired in the first driver 112 and the second driver 113, which are operating sources of the stopper 114. Therefore, for example, these drivers use power components such as a compact slim low-dust-generating cylinder operated by an air pressure, a space-saving cylinder with a guide, and the like, a linear guide with low friction and low noise configured to support a cylinder drive shaft such that the drive shaft does not move in any direction other than a direction of the drive shaft, and an electromagnetic valve.

The first driver 112 is mounted on the frame 110, and the second driver 113 is mounted on the first driver 112. However, depending on a type of processing apparatus 10, a size of area 111, a shape of robot arm 18, a shape of stopper 114, and a size of the wafer, the first driver and the second driver may not be configured to be combined with each other. For example, depending on a combination of a material, a shape, and the like of stopper 114, it is also possible to achieve the fall prevention by the movement of the stopper fixed to first driver 112 configured to move linearly in a direction approximately parallel to the opening.

In the spare cassette shelf 16 on which the stopper 114 is installed, the opening of the cassette 2 faces the X2 direction, which is the same direction as the direction in which the cassette transfer robot 17 takes out the cassette 2. Further, a predetermined gap g is set between the stopper 114 and the wafer 1 aligned at the innermost position. In other words, by setting the predetermined gap g on the opening side of the cassette 2, even in a case where wafers 1 are present at different positions within a range of the gap, the entirety of the wafers 1 may be prevented from falling, and the cassette 2 may be safely transferred by the cassette transfer robot 17. A design dimension of the gap g is, for example, 1 mm. Considering an assembly dimension tolerance, the stopper 114 may be fixed near a tip of the arm 113b such that the gap g may be regulated. The gap g includes zero. In that case, a moving speed and a pressure of the second cylinder 113a may be appropriately regulated.

The stopper 114 may be formed in a shape that increases a secondary moment of a cross section in the X2 direction, which is a direction in which the wafer 1 jumps out, for example, with a substantially rectangular cross section. As long as an effect of fall prevention is confirmed, the number, shape, and position of the stopper may not be limited.

Further, the material of the stopper 114 is, for example, the same as that of the cassette 2, and is a thermoplastic PEEK (polyether ether ketone) resin that prevents contamination of the wafer 1. Other materials with the same level of contamination prevention effect, strength, abrasion resistance, dimensional stability, and the like may also be used.

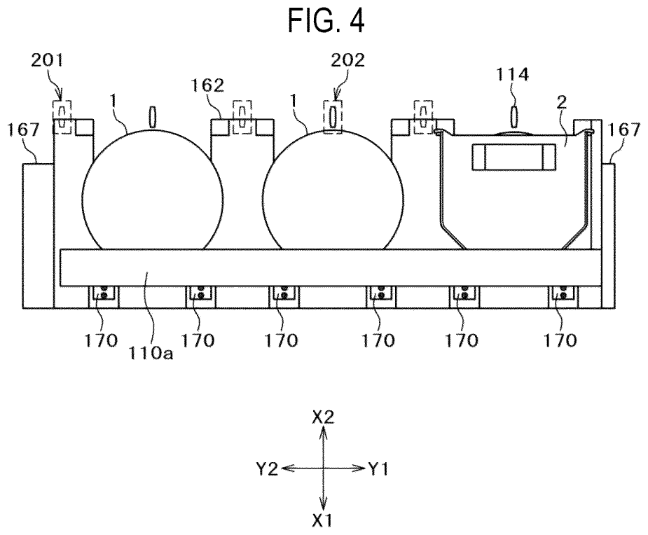

As shown in FIG. 4, the stopper 114 is installed so as to be movable between a first position 201 and a second position 202 by the first driver 112 and the second driver 113 described above. In other words, the first position 201 is set on the X2 side of the lower plate 161 or the upper plate 162, and the second position 202 is set at a position approximately at the center of the opening of the cassette 2. Since the first position 201 is located outside a Y-direction length of the cassette 2 and at the end of the lower plate 161 or the upper plate 162, the operation of the cassette transfer robot 17 is not affected, i.e., the transfer of the cassette 2 is not hindered. Since the second position 202 is set at a position where the cassette 2 or the wafer 1 in the cassette 2 may be prevented from falling, i.e., approximately at the center of the opening, one stopper 114 may perform a fall prevention function. In FIG. 4, the wafer 1 is shown on the upper plate 162. However, the wafer 1 is stored in the cassette 2, which is omitted.

### (Cassette Shelf)

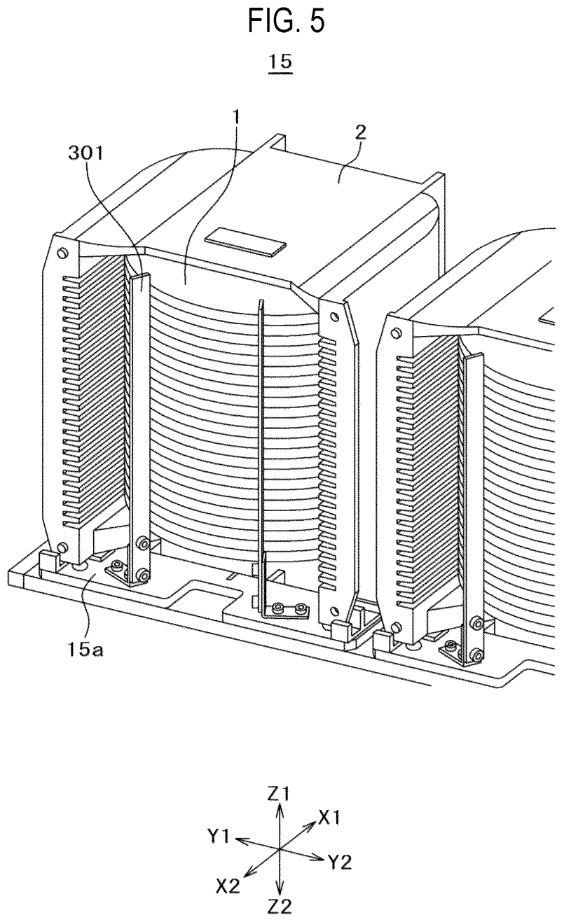

The cassette shelf 15 will be described with reference to FIG. 5. The cassette shelf 15 stores the cassettes 2 with their openings facing in the opposite direction to the direction in which the cassette transfer robot 17 takes out the cassettes 2 from the spare cassette shelf 16.

The cassette shelf 15 is provided with fixed stoppers 301 extending in the wafer arrangement direction so as to form a predetermined gap between the fixed stoppers 301 and the wafers arranged at the innermost position when viewed from the opening of the cassette stored therein. The fixed stopper 301 differs from the stopper 114 described with regard to the spare cassette shelf 16, and a lower side of the fixed stopper 301 is fixed in advance with screws or the like to the plate 15a where the cassettes 2 are mounted on a shelf portion other than a transfer shelf and is installed almost vertically with respect to the wafers 1 stored in the cassettes 2. In other words, since being formed with a fixed structure, the fixed stopper 301 always achieves a fall prevention effect on the cassettes 2 and the wafers 1 regardless of an operation of the processing apparatus 10 or an operation of the cassette transfer robot 17.

As long as the effect of fall prevention is confirmed, a shape and a position of the fixed stopper 301 may not be limited. The fixed stopper 301 may be a square pillar with a substantially rectangular cross section, or may be a polygonal pillar or a circular pillar. Further, two fixed stopper 301 is installed on left and right sides of the wafer opening of the cassette 2. As long as the effect of fall prevention is confirmed, the number and the position of the fixed stopper 301 may not be limited. Similar to the stopper 114 of the spare cassette shelf 16, in consideration of a possibility of contact with the wafers 1, an area facing the wafers 1 may be as small as possible to minimize a physical damage to the wafers 1 due to friction or the like.

Further, similar to the stopper 114 described above, material of the fixed stopper 301 may the same material as the cassette 2, i.e., a thermoplastic PEEK resin that prevents contamination of the wafers 1. Other resins with the same level of contamination prevention effect, strength, abrasion resistance, dimensional stability, etc. may also be used as the material.

### (Controller)

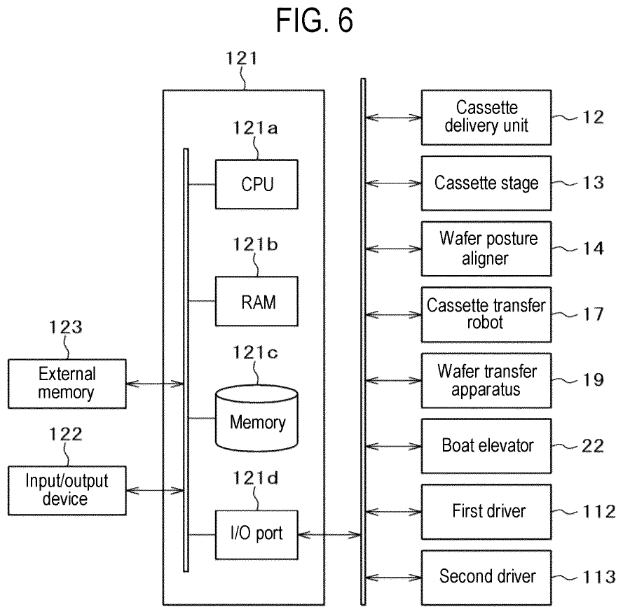

As shown in FIG. 6, the controller 121, which is a control part, is constituted as a computer including a central processing unit (CPU) 121a, a random access memory (CPU) 121b, a memory 121c, and an I/O port 121d. The RAM 121b, the memory 121c, and the I/O port 121d are configured to be capable of communicating with the CPU 121a via an internal bus. An input/output device 122, which is constituted as, for example, a touch panel or the like, and an external memory 123 are connected to the controller 121.

The memory 121c is constituted by, for example, a flash memory, a hard disk drive (HDD), or the like. A control program that controls the operation of the substrate processing apparatus, a process recipe in which procedures and conditions of the substrate processing to be described below are written, and the like are readably stored in the memory 121c. The recipe is combined to enables the controller 121 to execute the procedures in the substrate processing process described below to obtain a predetermined result, and is a high-level language compared to the control program. The control program and the recipe are generally called a program. The memory 121c also sequentially stores log information that records an operation and a state of the apparatus. The RAM 121b is constituted as a memory area (work area) in which the programs and data read by the CPU 121a are temporarily held.

The I/O port 121d is connected to the cassette delivery unit 12, the cassette stage 13, the wafer posture aligner 14, the cassette transfer robot 17, the wafer transfer apparatus 19, the boat elevator 22, the first driver 112 for the stopper 114, the second driver 113 for the stopper 114, and the like.

The CPU 121a is configured to read a control program from the memory 121c and execute the control program, and is also configured to read a wafer recipe from the memory 121c in response to an input of an operation command from the input/output device 122. The CPU 121a is configured to, in accordance with the contents of the read recipe, control a posture alignment operation of the cassette delivery unit 12, a rotation operation of the cassette stage 13, an operation of the wafer posture aligner 14, an operation of the robot arm 18 of the cassette transfer robot 17, rotation and elevating movements of the wafer transfer apparatus 19, an elevating operation of the boat elevator 22, operations of the first driver 112 and the second driver 113 for the stopper 114, and the like.

Such a controller 121 may control the movement of the cassette 2 by the cassette transfer robot 17 and control the stopper 114 described below.

When the cassette transfer robot 17 moves the cassette 2 to or from the spare cassette shelf 16, the fall preventer corresponding to the cassette 2 is controlled to move to a first position 201, i.e., a position that does not hinder the movement of the cassette 2.

In addition, when the cassette transfer robot 17 starts to move from a standby position (home position) when not accessing the cassettes 2 stored in the spare cassette shelf 16, the fall preventers corresponding to the cassettes 2 stored in the spare cassette shelf 16 are controlled to move to the first position 201. Further, the fall preventers are controlled to move to a second position 202 after a predetermined time elapses since the cassette transfer robot 17 returns to the home position. Through such a cooperation, it is possible to reduce a time lag between a transport operation of the cassette 2 and a startup of the fall preventer, in other words, to reduce a risk of losing the wafers 1.

The controller 121 may be configured by installing the above-mentioned program and recipe stored in an external memory (e.g., a magnetic disk such as a hard disk, or a semiconductor memory such as a USB memory) 123 into a computer. The memory 121c and the external memory 123 are constituted as a tangible computer-readable recording medium.

Hereinafter, these will be generally and simply referred to as a recording medium. When the term “recording medium” is used in the present disclosure, it may include the memory 121c, the external memory 123, or both. The program may be provided to the computer by using a communication means or unit such as the Internet or a dedicated line instead of instead of using the external memory 123.

### (2) Method of Processing Substrate

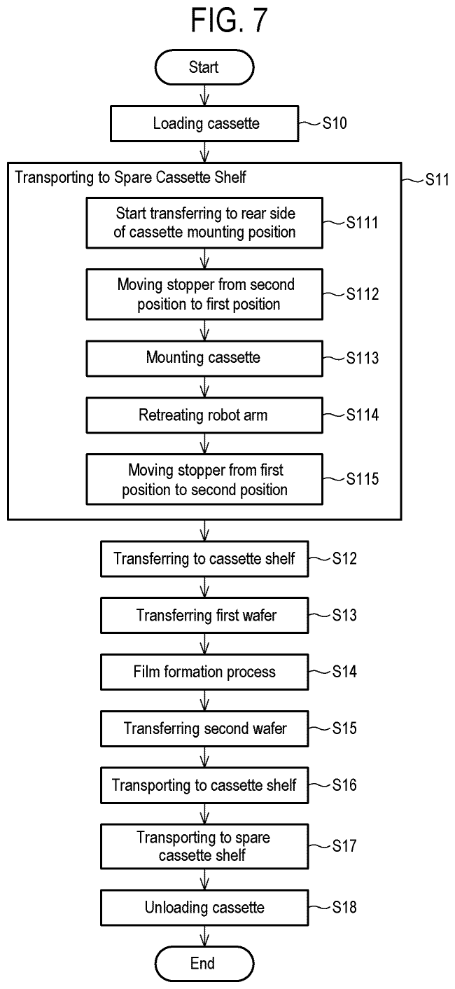

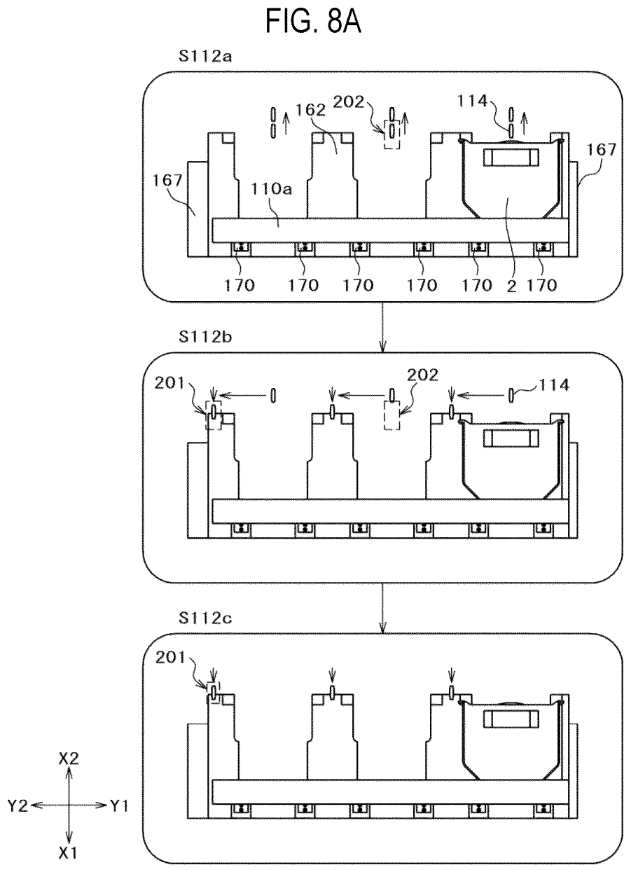

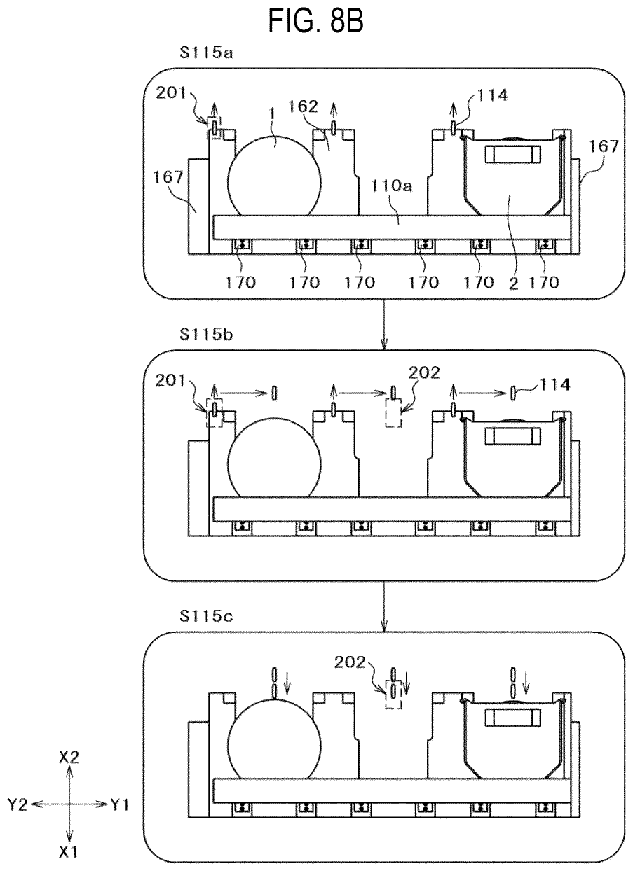

Next, a method of processing a substrate by using the processing apparatus 10 will be described with reference to FIGS. 7, 8A, and 8B. In the method of processing the substrate described herein, a film formation process of forming a film on a wafer 1, which is a process of manufacturing a semiconductor device, will be described by way of example using the reaction tube 31 of the processing apparatus 10 described above. In the following description, an operation of each component constituting the processing apparatus 10 is controlled by the controller 121.

### (Cassette Loading: S10)

Unprocessed wafers 1 are charged into the cassette 2. The cassette is transported to the front side of the housing 11 by an external transfer apparatus (not shown) and mounted (loaded) on the cassette stage 13 of the cassette delivery unit 12. At this time, the wafers 1 in the cassette 2 are kept vertical. The postures of the wafers 1 are aligned by the wafer posture aligner 14, and the cassette stage 13 is rotated 90 degrees to rotate the cassette 2 by 90 degrees. Inside the processing apparatus 10, the wafers 1 in the cassette 2 are kept in a horizontal posture, and the positions of the wafers 1 in the cassette 2 are aligned by the movement of the cassette 2.

### (Transporting to Spare Cassette Shelf: S11)

Before the cassette 2 starts to be transported to the spare cassette shelf 16, as shown in FIG. 4 described above, the stopper 114 is at such a position that the cassette 2 and the wafers 1 are prevented from falling at the second position 202.

The cassette transfer robot 17 starts transferring the cassette 2 from the cassette stage 13 to a rear side of a mounting position of the spare cassette shelf 16 (S111). At the same time as the start operation of the cassette transfer robot 17, as shown in FIG. 8A, the stopper 114 is moved from the second position 202 to the first position 201 where the transfer of the cassette 2 is not hindered, by the operation of the second driver 113, the first driver 112, and the second driver 113 in the named order under the control of the controller 121 (S112). That is, the stopper 114 is moved from the second position 202 in the X2 direction and spaced apart from the wafers 1 (S112a). Next, the stopper 114 is moved in the Y2 direction (S112b), and then moved in the X1 direction so as to be arranged at the first position 201 (S112c).

Next, the cassette transfer robot 17 mounts the cassette 2 at a predetermined mounting position in the spare cassette shelf 16 (S113).

The cassette transfer robot 17 retreats the robot arm 18 from the spare cassette shelf 16 and moves toward a home position or another destination (S114).

After the cassette transfer robot 17 is retreated from the spare cassette shelf 16, the stopper 114 is moved from the first position 201 to the second position 202 by the operations of the second driver 113, the first driver 112, and the second driver 113 in the named order under the control of the controller 121, as shown in FIG. 8B (S115). That is, the stopper 114 starts moving in the X2 direction from the first position 201 (S115a). Then, the stopper 114 moves in the Y1 direction to the front side of the opening of the cassette 2 (S115b). Next, the stopper 114 moves in the X1 direction and is arranged at the second position 202 (S115c). To clarify a position of the stopper 114 with respect to the wafers 1, the transferred cassette 2 on the left side is not illustrated.

Further, when a predetermined time elapses after the cassette 2 is unloaded from the spare cassette shelf 16 and the cassette transfer robot 17 returns to the standby position, the stopper 114 is moved to the second position 202 under the control of the controller 121. That is, basically, the stopper 114 always exists at the second position to prevent at least one cassette 2 and the wafers 1 from falling, and move between the first position 201 and the second position 202 in conjunction with the operation of the cassette transfer robot 17.

In the embodiments of the present disclosure, three cassettes are arranged on each stage of the spare cassette shelf 16 in a horizontal direction. In this case, the stopper 114 is operated in a lump for six cassettes across two stages, and does not interfere with operations of the cassette transfer robot 17 other than the operation of the robot arm 18.

### (Transporting to Cassette Shelf Transport: S12)

Next, the cassette 2 is taken out from the spare cassette shelf 16 and held by the robot arm 18 of the cassette transfer robot 17, and is transferred from the cassette shelf 15 or the spare cassette shelf 16 to a transfer shelf located at a position in the cassette shelf 15 facing the wafer transfer apparatus 19. In this case, at the same time as the cassette transfer robot 17 starts the transport operation, the stopper 114 is moved by the controller 121 from the second position 202 to the first position 201 where the transfer of the cassette 2 is not hindered, in the same manner as in the above-mentioned step S112. After being unloaded from the spare cassette shelf 16, the cassette 2 is moved from the first position 201 to the second position 202 in the same manner as in the above-mentioned step S115.

### (Transferring First Wafer: S13)

A horizontal wafer 1 in the cassette 2 mounted on the cassette shelf 15 or the transfer shelf is transferred to and loaded into the boat 25 by the wafer transfer apparatus 19.

### (Film Formation Process: S14)

Next, the boat 25 is loaded into the reaction tube 31 by the boat elevator 22. When the loading of the boat 25 (wafers 1) into the reaction tube 31 is completed, for example, a precursor gas and a reaction gas are supplied to form a film on the wafer 1 under predetermined conditions.

### (Transferring Second Wafer: S15)

After the film formation process, the boat 25 is taken out from the reaction tube 31 by the boat elevator 22. Next, the processed wafers 1 in the boat 25 are transferred by the wafer transfer apparatus 19 into the cassette 2 on the transfer shelf.

### (Transporting to Cassette Shelf: S16)

Next, the cassette 2 on the transfer shelf is transferred to the cassette shelf 15 by the robot arm 18.

### (Transporting to Spare Cassette Shelf: S17)

Next, the cassette 2 is held by the robot arm 18 of the cassette transfer robot 17 and transferred to the spare cassette shelf 16. At this time, simultaneously with start of operation of the cassette transfer robot 17, the stopper 114 installed at the spare cassette shelf 16 is moved from the second position 202 to the first position 201 by the controller 121 in the same manner as in step S112 described above, so as not to hinder the loading of the cassette 2. After the cassette 2 is loaded on the spare cassette shelf 16, the stopper 114 is moved from the first position 201 to the second position 202 by the controller 121 in the same manner as in step S115 described above.

### (Unloading Cassette: S18)

When the cassette 2 is to be unloaded from the processing apparatus 10, the stopper 114 is moved from the second position 202 to the first position 201 by the controller 121 in the same manner as in the above-described step S112, and then the cassette 2 is transferred by the robot arm 18 from the spare cassette shelf 16 to the cassette stage 13 of the cassette delivery unit 12.

The movement of the stopper 114 of the spare cassette shelf 16 between the first position 201 and the second position 202 by the controller 121 of the processing apparatus 10 is described above based on the operation of the cassette transfer robot 17 and the loading or unloading of the cassette 2 into or from the spare cassette shelf 16. In a case where it is difficult to incorporate the operation of the stopper 114 into the controller 121 in terms of software, a separate controller, for example, a programmable logic controller (hereinafter, referred to as PLC) capable of performing various processes, may be used for control in association with a home sensor of each axis of the cassette transfer robot 17 as shown below. By using the PLC, it is also possible to avoid interference with the operation by the controller 121.

(a) When a state of at least one home sensor (not shown) of a CS axis or a CZ axis of the cassette transfer robot 17 is changed from an ON state to an OFF state, i.e., when at least one home sensor is moved from a home position, the stopper 114 starts moving from the second position 202 to the first position 201.

(b) Until the movement of the stopper 114 from the second position 202 to the first position 201 is completed, the operations of the cassette transfer robot 17 (CS/CZ axes) and the robot arm 18 (CX axis) are temporarily stopped.

(c) After the stopper 114 moves to the first position 201, the cassette transfer robot 17 (CS/CZ axes) and the robot arm 18 (CX axis) may resume their operations by canceling the temporary stop.

(d) The home sensors of the CS and CZ axes of the cassette transfer robot 17 are kept in the ON state, i.e., at the home position for a certain period of time, and the stopper 114 starts moving from the first position 201 to the second position 202.

According to the above-described embodiments of the present disclosure, one or more of the following effects may be obtained.

When the robot arm 18 of the cassette transfer robot 17 is in a state other than a state where the robot arm 18 enters the spare cassette shelf 16, the stopper 114 is moved to the opening side of the cassette 2 by the first driver 112 and the second driver 113 and maintained approximately perpendicular to the arrangement of the wafers 1, thereby reliably preventing the cassettes 2 and the wafers 1 mounted on the spare cassette shelf 16 from falling.

The drivers of the fall preventer, i.e., the first driver 112 which moves linearly in the direction approximately parallel to the opening through which the wafers are inserted or removed, and the second driver 113 which moves linearly in the direction approximately perpendicular to the opening, are shared for multiple cassettes, which makes it possible to construct the drivers in a cost-effective manner.

In a case where any wafer 1 protrudes from the cassette 2, the stopper 114 may provide an effect of pushing the wafer 1 inward, i.e., an alignment function, which may be used to align the wafer. As a result, after completion of the set substrate processing process, the wafer 1 may not be rearranged after the cassette 2 is transported to the cassette stage 13.

### OTHER EMBODIMENTS

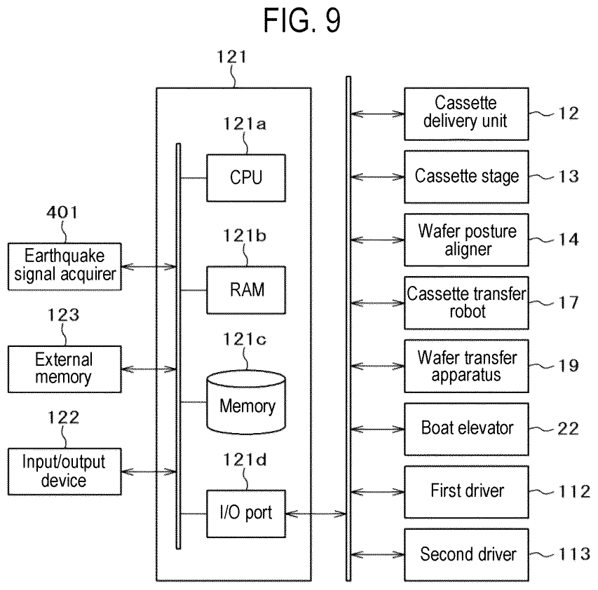

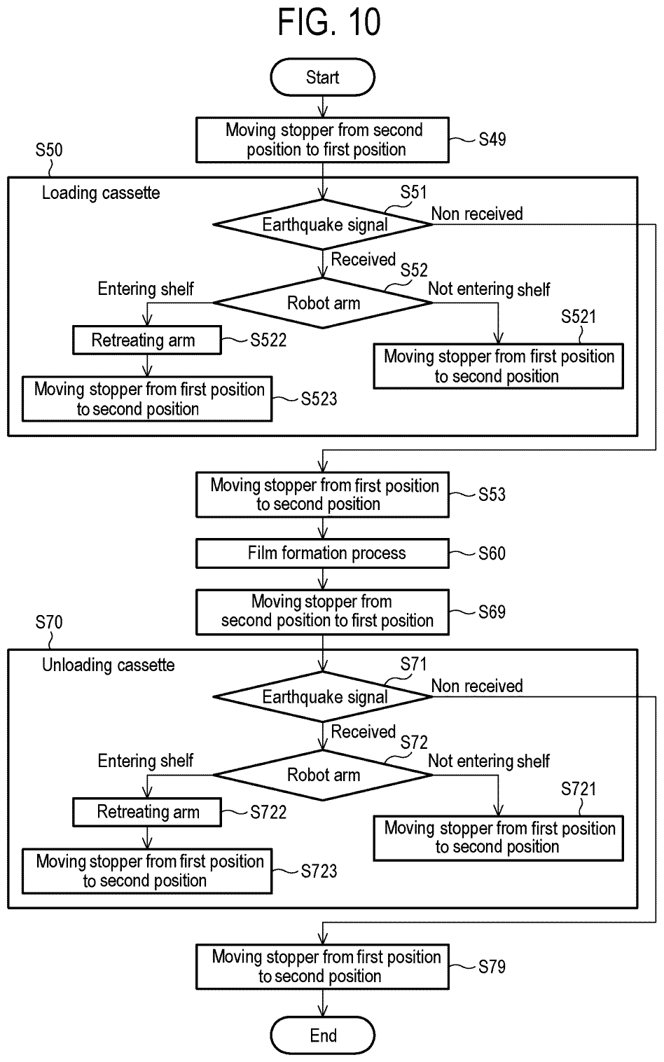

A controller 121 of a processing apparatus 10 according to other embodiments of the present disclosure and a method of processing a substrate by using the same will be described with reference to FIGS. 9 and 10.

As shown in FIG. 9, a basic configuration of the controller 121 according to other embodiments is similar to that of the above-described embodiments shown in FIG. 6. In FIG. 9, an earthquake signal acquirer 401 is additionally installed.

The earthquake signal acquirer 401 is configured to receive detection signals of an initial tremor (P) wave and/or a main shaking (S) wave. In FIG. 9, the earthquake signal acquirer 401 is shown as a block diagram attached to the controller 121. As long as being capable of receiving earthquake signals from the outside, the earthquake signal acquirer 401 may be built into the controller 121.

The controller 121 is configured to control a stop operation of the transporter and the processor in response to the detection signals of each of a P wave and an S wave when the earthquake signal acquirer 401 receives the detection signals. For example, the CPU 121a and the I/O port 121d are configured to operate and control the first driver 112 and the second driver 113 of the stopper 114 in the present disclosure when an earthquake occurs. In other words, when a first arriving P wave is detected, it is possible to immediately start an operation of movement to the second position 202 to prevent losses due to damages to the wafer 1, falling of wafer 1, and the like. That is, the controller 121 may determine whether the P wave or the S wave is detected, and may individually set the stop operations of the transporter and the processor.

Next, an operation of the stopper 114 in the process of loading or unloading a cassette to or from the spare cassette shelf 16 in the method of processing the substrate when an earthquake signal is received will be described with reference to FIG. 10. Since the process of loading or unloading wafers to or from the spare cassette shelf 16 when an earthquake signal is not received, the transport process between the process chamber 32 and the cassette shelf 15 in the processing apparatus 10, and the film formation process are the same as those in the above-described embodiments, detailed descriptions thereof will be omitted. In addition, the operation method on the movement of the stopper 114 between the first position 201 and the second position 202 is the same as that in the above-described embodiments shown in FIGS. 8A and 8B.

(Moving Stopper from Second Position to First Position: S49)

After the cassette 2 is loaded into the same processing apparatus 10 as in step S10 of the above-described embodiments, the cassette transfer robot 17 transfers the cassette 2 to a rear side of the mounting position of the spare cassette shelf 16 in the same manner as step S111 of the above-described embodiments, i.e., starts transferring the cassette 2 toward the spare cassette shelf 16. At the same time as this start, the controller 121 performs a control of moving the stopper 114 from the second position 202 to the first position 201 that does not hinder the transfer of the cassette 2.

### (Loading Cassette/Receiving Earthquake Signal: S50, S51 and S52)

At this time, when the earthquake signal acquirer 401 receives a signal generated due to an earthquake, in a case the robot arm 18 of the cassette transfer robot 17 does not enter the spare cassette shelf 16, the controller 121 performs a control of moving the stopper 114 from the first position 201 to the second position 202 (S521).

On the other hand, in a case where the robot arm 18 of the cassette transfer robot 17 enters the spare cassette shelf 16, the controller 121 performs a control of immediately retreating the robot arm 18 (S522), and moving the stopper 114 from the first position 201 to the second position 202 (S523).

In a case where an earthquake signal is received during this cassette loading, the transfer or unloading of the cassette 2 to or from the spare cassette shelf 16 and the entire functions within the processing apparatus 10 are stopped until a manual release operation is performed.

(Moving Stopper from First Position to Second Position: S53)

In a case where no earthquake signal is received when the cassette 2 is loaded into the spare cassette shelf 16, the cassette 2 is transported from the spare cassette shelf 16 to the cassette shelf 15, and the stopper 114 of the spare cassette shelf 16 is moved from the first position 201 to the second position 202. Thereafter, S12 and S13 of the above-described embodiments are performed.

### (Film Formation Process: S60)

When loading of the boat 25 (wafers 1) into the reaction tube 31 is completed, for example, a precursor gas and a reaction gas are supplied to form a film on the wafer 1 under predetermined conditions. After film formation on the entire wafers is completed, the cassette 2 is transported to the cassette shelf 15 via the transfer shelf, in the same manner as S15 and S16 of the above-described embodiments.

(Moving Stopper from Second Position to First Position: S69)

When the transport from the cassette shelf 15 to the spare cassette shelf 16 starts, the controller 121 performs a control of moving the stopper 114 of the spare cassette shelf 16 from the second position 202 to the first position 201 (S69).

### (Unloading Cassette/Receiving Earthquake Signal: S70, S71 and S72)

At this time, when the earthquake signal acquirer 401 receives a signal generated due to an earthquake, in a case where the robot arm 18 of the cassette transfer robot 17 does not entered the spare cassette shelf 16, the controller 121 performs a control of moving the stopper 114 from the first position 201 to the second position 202 (S721).

On the other hand, in a case where the robot arm 18 of the cassette transfer robot 17 enters the spare cassette shelf 16, the controller 121 performs a control of immediately retreating the robot arm 18 (S722), and moving the stopper 114 from the first position 201 to the second position 202 (S723).

(Moving Stopper from First Position to Second Position: S79)

In a case where no earthquake signal is received when the wafers are unloaded to the spare cassette shelf 16, the controller 121 performs a control of moving the stopper 114 of the spare cassette shelf 16 from the first position 201 to the second position 202 after the transport from the cassette shelf 15 to the spare cassette shelf 16.

In a case where an earthquake signal is received during wafer unloading, transferring or unloading of the cassette 2 to or from the spare cassette shelf 16 and the entire functions within the processing apparatus 10 will be stopped until a manual release operation is performed, in the same manner as when the wafers are loaded.

When the cassette 2 is unloaded to the outside of the processing apparatus 10, as in S18 of the above-described embodiments, the controller 121 performs a control of moving the stopper 114 to the first position 201, and then transferring the cassette 2, by the robot arm 18, from the spare cassette shelf 16 to the cassette stage 13 of the cassette delivery unit 12.

The movement of the stopper 114 between the first position 201 and the second position 202 in the event of an earthquake occurring during the loading and unloading of the cassette 2 on the spare cassette shelf 16 is described above based on the movement and position of the robot arm 18 of the cassette transfer robot 17. Upon receiving an external earthquake signal, the movement and the position of the stopper 114 may also be respectively controlled in association with operating part of the apparatus shown below by a software operation.

When the stopper 114 is at the second position 202, the entire operating parts of the apparatus are prohibited from returning to their home positions or from moving from the home positions.

When the stopper 114 is at the first position 201, after the robot arm 18 (CX axis) returns to the home position, the cassette transfer robot 17 (CS/CZ axes) returns to its home position and the stopper 114 moves to the second position 202.

This aspect of earthquake signal reception also provides the same effects as those of the above-described embodiments. Under the control of the controller 121, the stopper 114 is moved to the opening side of the cassette 2 in conjunction with the movement of the cassette transfer robot 17 or the robot arm 18 and is kept approximately perpendicular to the arrangement of the wafers 1, thereby reliably preventing the cassettes 2 and the wafers 1 mounted on the spare cassette shelf 16 from falling.

In the above-described several embodiments, the example in which a film is formed by using a batch-type substrate processing apparatus configured to process a plurality of substrates at a time is described. The present disclosure is not limited to the above-described embodiments, and may be also suitably applied to, for example, a case where a film is formed by using a single-substrate-type substrate processing apparatus configured to process one or several substrates at a time. Further, in the above-described embodiments, the example in which a film is formed by using the substrate processing apparatus including a hot-wall-type process furnace is described. The present disclosure is not limited to the above-described embodiments, and may be also suitably applied to, for example, a case where a film is formed by using a substrate processing apparatus including a cold-wall-type process furnace.

When using these substrate processing apparatuses, each process may be performed under the same process procedures and conditions as in the above-described embodiments, and the same effects as in the above-described embodiments may be obtained.

According to the present disclosure in some embodiments, it is possible to prevent a substrate cassette stored on a spare cassette shelf in an apparatus from falling due to shaking such as an earthquake or the like.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
(a) a container storage configured to store at least one container configured to accommodate substrates; and
(b) at least one fall preventer a part of which is installed to be movable between a first position that does not hinder transfer of the at least one container and a second position that prevents the at least one container stored in the container storage or the substrates in the at least one container from falling.

2. The substrate processing apparatus of claim 1, wherein the at least one fall preventer includes a first driver configured to move linearly in a direction approximately parallel to an opening of the at least one container through which the substrates are inserted into and removed from the at least one container, a second driver configured to move linearly in a direction approximately perpendicular to the opening, and a stopper configured to be moved by the first driver and the second driver, and
wherein when moving the stopper from the first position to the second position, the stopper is moved to a front side of the opening by the first driver, and then the stopper is moved toward the substrates by the second driver.

3. The substrate processing apparatus of claim 2, wherein the at least one container includes a plurality of containers,
wherein the container storage is configured such that the plurality of containers is capable of being mounted along a plane parallel to the opening, and
wherein the stopper is installed for each of the plurality of containers.

4. The substrate processing apparatus of claim 2, further comprising:
a frame at least partially arranged over the at least one container and fixed to the container storage,
wherein the first driver is mounted on the frame, and the second driver is mounted on the first driver.

5. The substrate processing apparatus of claim 1, further comprising:
a cassette transfer apparatus installed in a same housing as the container storage and configured to move the at least one container to or from the container storage,
wherein the container storage is configured to hold the at least one container with an opening of the at least one container facing a same direction as a direction in which the cassette transfer apparatus takes out the at least one container from the container storage.

6. The substrate processing apparatus of claim 5, further comprising:
a controller configured to be capable of controlling the movement of the at least one container by the cassette transfer apparatus and controlling the at least one fall preventer corresponding to the at least one container to move to the first position when the cassette transfer apparatus moves the at least one container to the container storage and when the cassette transfer apparatus moves the at least one container from the container storage.

7. The substrate processing apparatus of claim 6, wherein the at least one fall preventer includes a plurality of fall preventers and the at least one container includes a plurality of containers, and
wherein the controller is further configured to be capable of performing a control to move the plurality of fall preventers corresponding to the plurality of containers stored in the container storage to the first position when the cassette transfer apparatus starts moving from a standby position where the cassette transfer apparatus does not access the plurality of containers stored in the container storage, and to move the plurality of fall preventers to the second position after a predetermined time elapses since the cassette transfer apparatus returns to the standby position.

8. The substrate processing apparatus of claim 6, wherein the controller is further configured to be capable of preferentially controlling the at least one fall preventer to move to the second position when functions of the at least one fall preventer are entirely stopped due to reception of an earthquake signal.

9. The substrate processing apparatus of claim 2, wherein the stopper is further configured to extend in substantially a same direction as an arrangement direction of the substrates in the at least one container near the opening of the at least one container and prevent the substrates from jumping out of the at least one container, when the stopper is at the second position.

10. The substrate processing apparatus of claim 6, wherein the at least one fall preventer is configured to perform an alignment which enables a substrate of the substrates that protrudes from the at least one container to be stored into the at least one container when the at least one fall preventer moves to the second position.

11. The substrate processing apparatus of claim 9, wherein the second position is set such that a predetermined gap is formed between the stopper and a substrate of the substrates that is aligned at an innermost position when viewed from a vicinity of the opening.

12. The substrate processing apparatus of claim 11, wherein the predetermined gap is set such that the substrates which are located at different positions within a range of the predetermined gap is capable of being transferred by a cassette transfer apparatus configured to move the at least one container to or from the container storage.

13. The substrate processing apparatus of claim 5, further comprising:
a main storage configured to store the at least one container configured to accommodate the substrates with the opening of the at least one container facing in a direction opposite to a direction in which the cassette transfer apparatus takes out the at least one container from a shelf,
wherein the main storage includes a fixed stopper extending in an arrangement direction of the substrates such that a predetermined gap is formed between the fixed stopper and a substrate of the substrates that is aligned at an innermost position when viewed from the opening of the at least one container stored in the main storage.

14. A substrate fall preventer, comprising:
a first driver configured to move linearly in a direction approximately parallel to an opening of a container mounted on a shelf and configured to accommodate substrates;
a second driver configured to move linearly in a direction approximately perpendicular to the opening; and
a stopper configured to be moved by the first driver and the second driver between a first position that does not hinder transfer of the container and a second position that prevents the container stored in a container storage or the substrates in the container from falling.

15. A method of processing a substrate, comprising:
(a) receiving substrates contained in a container and loading the substrates into a process furnace;
(b) processing the substrates in the process furnace; and
(c) taking out the substrates from the process furnace and storing the substrates into the container,
wherein at least one selected from the group of (a) and (c) includes moving a fall preventer, which is installed in a container storage configured to store the container in a substrate processing apparatus, between a first position that does not hinder transfer of the container and a second position that prevents the container stored in the container storage or the substrates in the container from falling.

16. The method of claim 15, wherein (a) is performed while keeping the substrates in a horizontal posture within the container, and positions of the substrates in the container are aligned by the act of moving the fall preventer.

17. A method of manufacturing a semiconductor device, comprising the method of claim 15.

18. A non-transitory computer-readable recording medium storing a program that causes, by a computer, a substrate processing apparatus to perform a process comprising the method of claim 15.
